(19) United States
(12) Patent Application Publication
(10) Pub. No.: US 2025/0220984 A1
(43) Pub. Date: Jul. 3, 2025

(54) SEMICONDUCTOR DEVICE STRUCTURE WITH BACKSIDE PICK-UP REGION AND METHOD OF MANUFACTURING THE SAME

(71) Applicant: NANYA TECHNOLOGY CORPORATION, NEW TAIPEI CITY (TW)

(72) Inventor: HSIH-YANG CHIU, TAOYUAN CITY (TW)

(21) Appl. No.: 19/082,547

(22) Filed: Mar. 18, 2025

Related U.S. Application Data
(63) Continuation-in-part of application No. 18/536,597, filed on Dec. 12, 2023.

(51) Int. Cl. H10D 62/10; H01L 21/762; H10D 84/85

(52) U.S. Cl. CPC H10D 62/105; H01L 21/76224; H10D 84/859

(57) ABSTRACT

A semiconductor device structure and method of manufacturing the same are provided. The semiconductor device structure includes a substrate, a first well region, a source/drain (S/D) feature, and a pick-up region. The substrate has a first surface and a second surface opposite to the first surface. The first well region abuts the second surface of the substrate and has a first conducive type. The S/D feature abuts the second surface of the substrate and has a second conductivity type different from the first conductivity type. The pick-up region abuts the first surface of the substrate and has the first conductivity type.

### CROSS-REFERENCE TO RELATED APPLICATION

This application is a Continuation-in-part application of U.S. Non-Provisional application Ser. No. 18/536,597 filed Dec. 12, 2023, which is incorporated herein by reference in its entirety.

### TECHNICAL FIELD

The present disclosure relates to a semiconductor device structure, and more particularly, to a semiconductor device structure with a backside pick-up region and a method of manufacturing the same.

### DISCUSSION OF THE BACKGROUND

With the rapid growth of the electronics industry, integrated circuits (ICs) are becoming more powerful and smaller, with advances in materials and design leading to successive generations of smaller and more complex circuits.

Dynamic random-access memory (DRAM) is a type of random-access memory used for storing bits of data in separate capacitors within an integrated circuit. A DRAM is commonly arranged in a square array, with one capacitor and one transistor per cell. A vertical transistor has been developed for the 4F2 DRAM cell, wherein F represents a photolithographic minimum feature width or a critical dimension (CD). However, there are still challenges to improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device structure. The semiconductor device structure includes a substrate having a first surface and a second surface opposite to the first surface; an isolation structure disposed in the substrate and protruding from the second surface of the substrate; a first well region abutting the second surface of the substrate and having a first conductivity type; a source/drain (S/D) feature abutting the second surface of the substrate and having a second conductivity type different from the first conductivity type; and a first pick-up region abutting the first surface of the substrate and having the first conductivity type. The isolation structure comprises a first liner layer disposed in the substrate, a second liner layer disposed over the first liner layer and protruding from the second surface of the substrate, a third liner layer disposed over the second liner layer, and a trench filling layer disposed over the third liner layer. The second liner layer includes a lower portion disposed in the substrate and an upper portion disposed on the lower portion and protruding from the second surface of the substrate. A thickness of the upper portion is greater than a thickness of the lower portion.

One aspect of the present disclosure provides a semiconductor device structure. The semiconductor device structure includes a substrate having a first surface and a second surface opposite to the first surface; an isolation layer disposed in the substrate and parallel to the first surface and the second surface; a pad oxide layer disposed over the second surface of the substrate; a pad nitride layer disposed over the pad oxide layer; and an isolation structure extending from a top surface of the pad nitride layer, penetrating the pad nitride layer and the pad oxide layer, and into the substrate. The isolation structure comprises a first liner layer disposed in the substrate, a second liner layer disposed over the first liner layer, a third liner layer disposed over the second liner layer, and a trench filling layer disposed over the third liner layer. The second liner layer includes an upper portion located between the pad oxide layer and the third liner layer and between the pad nitride layer and the third liner layer, and a lower portion located between the first liner layer and the third liner layer. A thickness of the upper portion of the second liner layer is greater than a thickness of the lower portion of the second liner layer.

Another aspect of the present disclosure provides a method of manufacturing a semiconductor device structure. The method includes providing a substrate having a first surface and a second surface opposite to the first surface; forming a pad oxide layer over the second surface of the substrate; forming a pad nitride layer over the pad oxide layer; forming an isolation structure extending from a top surface of the pad nitride layer, penetrating the pad nitride layer and the pad oxide layer, and into the substrate; forming a first well region abutting the second surface of the substrate; forming a source/drain (S/D) feature abutting the second surface of the substrate; and forming a pick-up region abutting the first surface of the substrate. The first well region has a first conducive type, the S/D feature has a second conductivity type different from the first conductivity type, and the pick-up region has the first conductivity type.

Another aspect of the present disclosure provides a method of manufacturing a semiconductor device structure. The method includes providing a substrate with an isolation layer disposed therein, wherein the substrate has a first surface and a second surface opposite to the first surface; forming a pad oxide layer over the second surface of the substrate; forming a pad nitride layer over the pad oxide layer; and forming an isolation structure extending from a top surface of the pad nitride layer, penetrating the pad nitride layer and the pad oxide layer, and into the substrate.

The embodiments of the present disclosure provide a semiconductor device structure. The semiconductor device structure includes a pick-up region and a source/drain feature on opposite two surfaces of a substrate. The pick-up region is configured to provide a low-resistance path for a drift current to flow out of the semiconductor device structure through a backside surface. The pick-up region can provide a relatively short path for transmitting the drift current and reduce the leakage caused by a cosmic ray incident to the semiconductor device structure.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a cross-sectional diagram of a semiconductor device structure in accordance with some embodiments of the present disclosure.

FIG. 2 shows a schematic view of a semiconductor device structure including a depletion region in accordance with some embodiments of the present disclosure.

FIG. 3 shows a schematic view of a semiconductor device structure including an induced depletion region in accordance with some embodiments of the present disclosure.

FIG. 4 illustrates one or more stages of an exemplary method of manufacturing a semiconductor device structure in accordance with some embodiments of the present disclosure.

FIG. 5 illustrates one or more stages of an exemplary method of manufacturing a semiconductor device structure in accordance with some embodiments of the present disclosure.

FIG. 6 illustrates one or more stages of an exemplary method of manufacturing a semiconductor device structure in accordance with some embodiments of the present disclosure.

FIG. 7 illustrates one or more stages of an exemplary method of manufacturing a semiconductor device structure in accordance with some embodiments of the present disclosure.

FIG. 8 illustrates one or more stages of an exemplary method of manufacturing a semiconductor device structure in accordance with some embodiments of the present disclosure.

FIG. 9 illustrates one or more stages of an exemplary method of manufacturing a semiconductor device structure in accordance with some embodiments of the present disclosure.

FIG. 10 illustrates one or more stages of an exemplary method of manufacturing a semiconductor device structure in accordance with some embodiments of the present disclosure.

FIG. 11 illustrates one or more stages of an exemplary method of manufacturing a semiconductor device structure in accordance with some embodiments of the present disclosure.

FIG. 12 illustrates one or more stages of an exemplary method of manufacturing a semiconductor device structure in accordance with some embodiments of the present disclosure.

FIG. 13 illustrates one or more stages of an exemplary method of manufacturing a semiconductor device structure in accordance with some embodiments of the present disclosure.

FIG. 14 illustrates one or more stages of an exemplary method of manufacturing a semiconductor device structure in accordance with some embodiments of the present disclosure.

FIG. 15 illustrates one or more stages of an exemplary method of manufacturing a semiconductor device structure in accordance with some embodiments of the present disclosure.

FIG. 16 illustrates one or more stages of an exemplary method of manufacturing a semiconductor device structure in accordance with some embodiments of the present disclosure.

FIG. 17 illustrates one or more stages of an exemplary method of manufacturing a semiconductor device structure in accordance with some embodiments of the present disclosure.

FIG. 18 illustrates one or more stages of an exemplary method of manufacturing a semiconductor device structure in accordance with some embodiments of the present disclosure.

FIG. 19 illustrates one or more stages of an exemplary method of manufacturing a semiconductor device structure in accordance with some embodiments of the present disclosure.

FIG. 20 illustrates one or more stages of an exemplary method of manufacturing a semiconductor device structure in accordance with some embodiments of the present disclosure.

FIG. 21 shows a flowchart illustrating a method of manufacturing a semiconductor device structure in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that when an element or layer is referred to as being “connected to” or “coupled to” another element or layer, it can be directly connected to or coupled to another element or layer, or intervening elements or layers may be present.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about,” when used to modify a quantity of an ingredient, component, or reactant of the present disclosure, refers to variation in a numerical quantity that can occur, for example, through typical measuring and liquid handling procedures used for making concentrates or solutions. Furthermore, variation can occur from inadvertent error in measuring procedures, differences in manufacture, source, or purity of ingredients employed to make compositions or to carry out methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

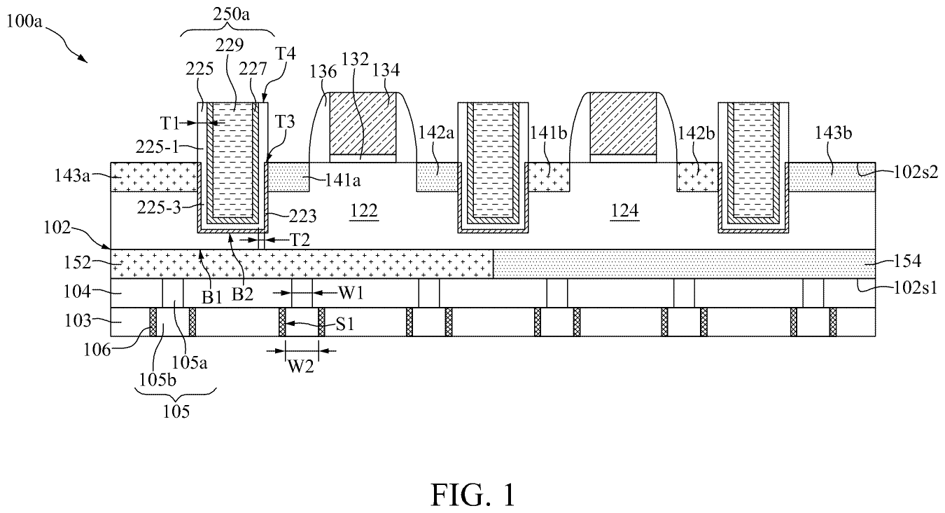

FIG. 1 illustrates a cross-sectional diagram of a semiconductor device structure 100a in accordance with some embodiments of the present disclosure. In some embodiments, the semiconductor device structure 100a may be a portion of a memory device, such as a dynamic random-access memory (DRAM) device, a one-time programming (OTP) memory device, a static random-access memory (SRAM) device, or other suitable memory devices.

In some embodiments, the semiconductor device structure 100a may include a substrate 102. The substrate 102 may be a semiconductor substrate, such as a bulk semiconductor, a semiconductor-on-insulator (SOI) substrate, or the like. The substrate 102 may include an elementary semiconductor, such as silicon or germanium, in a single crystal form, a polycrystalline form, or an amorphous form; a compound semiconductor material, including at least one of silicon carbide, gallium arsenide, gallium phosphide, indium phosphide, indium arsenide, and indium antimonide; an alloy semiconductor material, including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient SiGe feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 102 may have a multilayer structure, or the substrate 102 may include a multilayer compound semiconductor structure. The substrate 102 may have a surface 102s1 (or a lower surface or a backside surface) and a surface 102s2 (or an upper surface or an active surface) opposite to the surface 102s1. As used herein, the term “active surface” may refer to a surface on which a gate electrode and/or a source/drain feature is disposed.

In some embodiments, the semiconductor device structure 100a may include an isolation layer 104. The isolation layer 104 may be disposed on or under the surface 102s1 of the substrate 102. In some embodiments, the isolation layer 104 may include a dielectric material, such as silicon oxide, silicon nitride, silicon oxynitride, or other suitable materials.

In some embodiments, the semiconductor device structure 100a may include an isolation structure 250a. The isolation structure 250a may be at least partially embedded within the substrate 102 and may protrude from the surface 102s2. As shown in FIG. 1, in some embodiments, the isolation structure 250a of the semiconductor device structure 100a includes a first liner layer 223, a second liner layer 225 disposed over the first liner layer 223 and protruding from the surface 102s2, a third liner layer 227 disposed over the second liner layer 225, and a trench filling layer 229 disposed over the third liner layer 227. In some embodiments, the trench filling layer 229 is surrounded by the third liner layer 227, the third liner layer 227 is surrounded by the second liner layer 225, and the second liner layer 225 is separated from the well regions (e.g., well regions 122 and 124) by the first liner layer 223.

In some embodiments, a topmost surface T4 of the second liner layer 225 is higher than a topmost surface T3 of the first liner layer 223. In some embodiments, top surfaces of the second liner layer 225, the third liner layer 227 and the trench filling layer 229 are substantially coplanar with each other. In some embodiments, the second liner layer 225 includes an upper portion 225-1 disposed over the surface 102s2 and a lower portion 225-3 disposed below the surface 102s2, wherein a thickness T1 of the upper portion 225-1 of the second liner layer 225 is greater than a thickness T2 of the lower portion 225-3 of the second liner layer 225.

In some embodiments, the first liner layer 223, the second liner layer 225 and the third liner layer 227 of the isolation structure 250a are made of different materials. For example, the first liner layer 223 is made of silicon oxide, the second liner layer 225 is made of a nitride, and the third liner layer 227 is made of silicon oxynitride. Furthermore, a first etching selectivity exists between the second liner layer 225 and the trench filling layer 229, and a second etching selectivity exists between the third liner layer 227 and the trench filling layer 229.

In some embodiments, the semiconductor device structure 100a may include a well region 122. In some embodiments, the well region 122 may be located within the substrate 102. The well region 122 may surround the isolation structure 250a. In some embodiments, the well region 122 may cover a bottom surface B2 of the isolation structure 250a. The bottom surface B2 of the isolation structure 250a is higher than a bottom surface B1 of well regions 122. The well region 122 may have a first conductivity type, such as an n-type. In some embodiments, n-type dopants include arsenic (As), phosphorus (P), antimony (Sb), other group V elements, or a combination thereof. In some embodiments, a dopant concentration of the well region 122 may range between 1E14 atoms/cm³ and 1E16 atoms/cm³.

In some embodiments, the semiconductor device structure 100a may include a well region 124. In some embodiments, the well region 124 may be located within the substrate 102. The well region 124 may abut the well region 122. The well region 124 may surround the isolation structure 250a. In some embodiments, the well region 124 may cover the bottom surface B2 of the isolation structure 250a. The bottom surface B2 of the isolation structure 250a is higher than a bottom surface B1 of well regions 124. The well region 124 may have a second conductivity type different from the first conductivity type, such as a p-type. In some embodiments, p-type dopants include boron (B), other group III elements, or a combination thereof. In some embodiments, a dopant concentration of the well region 124 may range between 1E14 atoms/cm³ and 1E16 atoms/cm³.

In some embodiments, the semiconductor device structure 100a may include a gate dielectric layer 132. The gate dielectric layer 132 may be disposed on or over the surface 102s2 of the substrate 102. In some embodiments, the gate dielectric layer 132 may include dielectric materials, such as silicon oxide, silicon nitride, silicon oxynitride, another dielectric material, or a combination thereof. In some embodiments, the gate dielectric layer 132 is a multi-layer structure, including an interfacial layer and a high-k (dielectric constant greater than 4) dielectric layer. The interfacial layer can include dielectric materials, such as silicon oxide, silicon nitride, silicon oxynitride, another dielectric material, or a combination thereof. The high-k dielectric layer may include a high-k dielectric material, such as HfO₂, HfSiO, HfSiON, HfTaO, HfTiO, HfZrO, another suitable high-k dielectric material, or a combination thereof. In some embodiments, the high-k dielectric material may further be selected from metal oxide, metal nitride, metal silicate, transition metal oxide, transition metal nitride, transition metal silicate, metal oxynitride, metal aluminate, and/or a combination thereof.

In some embodiments, the semiconductor device structure 100a may include a gate electrode 134. The gate electrode 134 may be disposed on or over the gate dielectric layer 132. The gate electrode 134 may include polysilicon, silicon-germanium, and/or at least one metallic material, including elements and compounds such as Mo, Cu, W, Ti, Ta, TiN, TaN, NiSi, CoSi, or other suitable conductive materials known in the art. In some embodiments, the gate electrode 134 includes a work function metal layer that provides a metal gate with an n-type-metal work function or p-type-metal work function. The p-type-metal work function materials include materials such as ruthenium, palladium, platinum, cobalt, nickel, conductive metal oxide, or other suitable materials. The n-type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device structure 100a may include a spacer 136. The spacer 136 may be disposed on two opposite sides of the gate electrode 134 (or gate dielectric layer 132). In some embodiments, the spacer 136 includes a dielectric material, such as silicon nitride, silicon oxide, silicon carbonitride, silicon oxynitride, silicon oxy-carbo-nitride, or the like, and may have a single-layer structure or a multi-layer structure, including a plurality of dielectric layers.

In some embodiments, the semiconductor device structure 100a may include doped regions 141a and 142a. The doped regions 141a and 142a may be disposed within the substrate 102. The doped regions 141a and 142a may abut the surface 102s2 of the substrate 102. The doped regions 141a and 142a may be disposed within the well region 122. The doped regions 141a and 142a may collectively function as a source/drain (S/D) feature. The doped regions 141a and 142a may have a second conductivity type, such as a p-type. In some embodiments, dopant concentrations of the doped regions 141a and 142a may range between 1E17 atoms/cm³ and 1E20 atoms/cm³. In some embodiments, the well region 122, doped region 141a, and doped region 142a may define a p-type metal-oxide-semiconductor field-effect transistor (PMOS).

In some embodiments, the semiconductor device structure 100a may include a pick-up region 143a. The pick-up region 143a may be disposed within the substrate 102. The pick-up region 143a may abut the surface 102s2 of the substrate 102. The pick-up region 143a may be disposed within the well region 122. The pick-up region 143a may be spaced apart from the S/D feature (e.g., the doped regions 141a and 142a) by the isolation structure 250a. The pick-up region 143a may be configured to provide a low-resistance path for a current (e.g., a drift current) to flow out of the semiconductor device structure 100a through the surface 102s2 of the substrate 102. The pick-up region 143a may have a first conductivity type, such as an n-type. In some embodiments, a dopant concentration of the pick-up region 143a may range between 1E17 atoms/cm³ and 1E20 atoms/cm³.

In some embodiments, the semiconductor device structure 100a may include a doped region 141b and a doped region 142b. The doped regions 141b and 142b may be disposed within the substrate 102. The doped regions 141b and 142b may abut the surface 102s2 of the substrate 102. The doped regions 141b and 142b may be disposed within the well region 124. The doped regions 141b and 142b may collectively function as a source/drain feature. The doped regions 141b and 142b may have a first conductivity type, such as an n-type. In some embodiments, dopant concentrations of the doped regions 141b and 142b may range between 1E17 atoms/cm³ and 1E20 atoms/cm³. In some embodiments, the well region 124, doped region 141b, and doped region 142b may define an n-type metal-oxide-semiconductor field-effect transistor (NMOS).

In some embodiments, the semiconductor device structure 100a may include a pick-up region 143b. The pick-up region 143b may be disposed within the substrate 102. The pick-up region 143b may abut the surface 102s2 of the substrate 102. The pick-up region 143b may be disposed within the well region 124. The pick-up region 143b may be spaced apart from the S/D feature (e.g., the doped regions 141b and 142b) by the isolation structure 250a. The pick-up region 143b may be configured to provide a low-resistance path for a drift current to flow out of the semiconductor device structure 100a through the surface 102s2 of the substrate 102. The pick-up region 143b may have a second conductivity type, such as a p-type. In some embodiments, a dopant concentration of the pick-up region 143b may range between 1E17 atoms/cm³ and 1E20 atoms/cm³.

In some embodiments, the semiconductor device structure 100a may include a pick-up region 152. The pick-up region 152 may be disposed within the substrate 102. In some embodiments, the pick-up region 152 may abut the surface 102s1 of the substrate 102. In some embodiments, the pick-up region 152 may be exposed by the surface 102s1 of the substrate 102. In some embodiments, the pick-up region 152 may be spaced apart from the isolation structure 250a. In some embodiments, the pick-up region 152 may be located under the bottom surface B2 of the isolation structure 250a. In some embodiments, the pick-up region 152 may abut or be in contact with the well region 122.

In some embodiments, the pick-up region 152 may be configured to provide a low-resistance path for a drift current to flow out of the semiconductor device structure 100a through the surface 102s1 of the substrate 102. The pick-up region 152 may have a first conductivity type, such as an n-type. In some embodiments, a dopant concentration of the pick-up region 152 may be greater than that of the well region 122. In some embodiments, the dopant concentration of the pick-up region 152 may range between 1E17 atoms/cm³ and 1E20 atoms/cm³. In some embodiments, the dopant concentration of the pick-up region 152 may be substantially equal to that of the pick-up region 143a. In some embodiments, the pick-up region 152 may be electrically connected to ground. In some embodiments, a power same as the power imposed on the pick-up region 143a may also be imposed on the pick-up region 152.

In some embodiments, the semiconductor device structure 100a may include a pick-up region 154. The pick-up region 154 may be disposed within the substrate 102. In some embodiments, the pick-up region 154 may abut the surface 102s1 of the substrate 102. In some embodiments, the pick-up region 154 may be exposed by the surface 102s1 of the substrate 102. In some embodiments, the pick-up region 154 may be spaced apart from the isolation structure 250a. In some embodiments, the pick-up region 154 may be located under the bottom surface B2 of the isolation structure 250a. In some embodiments, the pick-up region 154 may abut or be in contact with the well region 124.

In some embodiments, the pick-up region 154 may be configured to provide a low-resistance path for a drift current to flow out of the semiconductor device structure 100a through the surface 102s1 of the substrate 102. The pick-up region 154 may have a second conductivity type, such as a p-type. In some embodiments, a dopant concentration of the pick-up region 154 may be greater than that of the well region 124. In some embodiments, the dopant concentration of the pick-up region 154 may range between 1E17 atoms/cm³ and 1E20 atoms/cm³. In some embodiments, the dopant concentration of the pick-up region 154 may be substantially equal to that of the pick-up region 143b. In some embodiments, the pick-up region 154 may be electrically connected to ground. In some embodiments, a power same as the power imposed on the pick-up region 143b may also be imposed on the pick-up region 154.

In some embodiments, the semiconductor device structure 100a may include a passivation layer 103. The passivation layer 103 may be disposed on or under the isolation layer 104. In some embodiments, the passivation layer 103 includes dielectric materials, such as spin-on glass (SOG), silicon oxide, silicon oxynitride, silicon nitride, or the like. In other embodiments, the passivation layer 103 may include polymers, BCB, PBO, PI, or other suitable materials.

In some embodiments, the semiconductor device structure 100a may include conductive vias 105. The conductive via 105 may consist of a first portion 105a disposed on or under the surface 102s1 of the substrate 102 and a second portion 105b disposed on or under the first portion 105a. In some embodiments, the first portion 105a extends through and is surrounded by the isolation layer 104. The second portion 105b extends through and is surrounded by the passivation layer 103 and is coupled with the first portion 105a. In some embodiments, the conductive via 105 is a through substrate via (TSV). Additionally, the conductive via 105 may be in contact with or electrically connected to the pick-up region 152 or 154 and electrically connected to ground. In some embodiments, the conductive via 105 includes conductive materials, such as gold, silver, copper, nickel, tungsten, aluminum, tin, alloys thereof or the like.

In some embodiments, a width W1 of the first portion 105a is substantially less than a width W2 of the second portion 105b. The width W1 of the first portion 105a is in a range of about 2 μm to about 10 μm. The width W2 of the second portion 105b is in a range of about 4 μm to about 10 μm. In some embodiments, the width W2 of the second portion 105b is about 7 μm.

In some embodiments, the semiconductor structure 100a may include a dielectric liner 106 positioned between the conductive via 105 and the passivation layer 103. In some embodiments, a top surface of the dielectric liner 106 is substantially coplanar with a top surface of the passivation layer 103 and a top surface of the second portion 105b of the conductive via 105.

In some embodiments, the dielectric liner 106 is disposed between the second portion 105b and the passivation layer 103. The dielectric liner 106 extends vertically along a sidewall S1 of the second portion 105b and through the passivation layer 103. In some embodiments, the dielectric liner 106 is disposed on or below and in contact with the isolation layer 104. In some embodiments, the dielectric liner 106 may include a dielectric material, such as an oxide or the like.

It should be noted that, as shown in FIG. 1, the first portion 105a of the conductive via 105 is surrounded by the isolation layer 104 and is not exposed to the dielectric liner 106, while the second portion 105b of the conductive via 105 is coupled with the first portion 105a and is surrounded by the passivation layer 103.

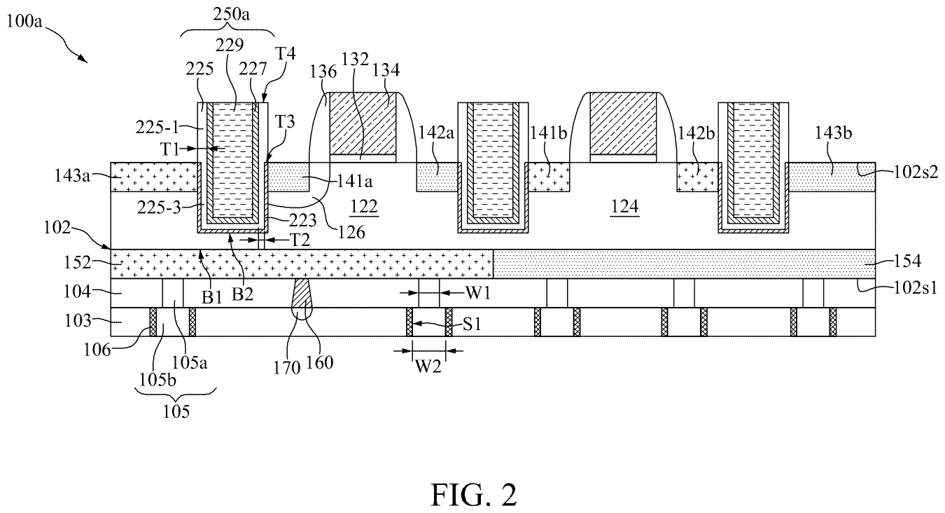

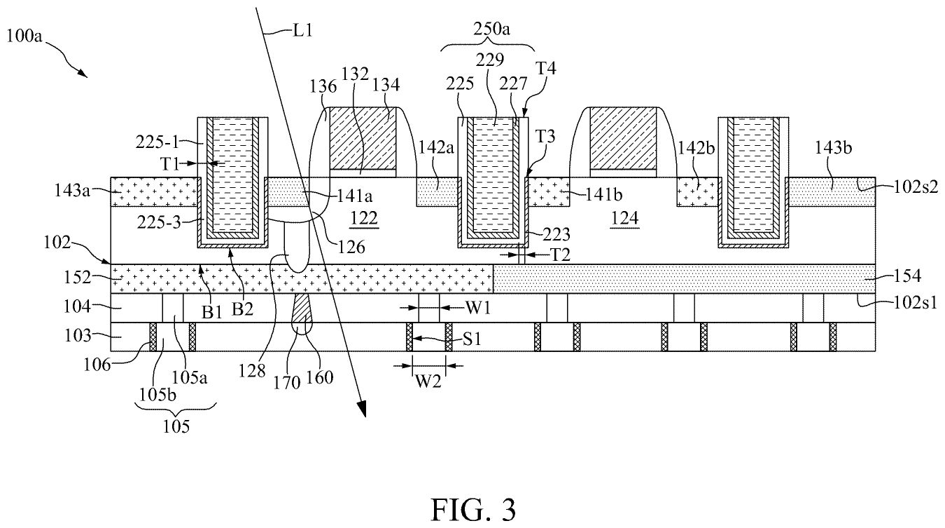

FIGS. 2 and 3 are schematic views illustrating a semiconductor device structure 100a including a depletion region and an induced depletion region.

As shown in FIG. 2, the semiconductor device structure 100a may include a depletion 126 between the doped region 141a and the well region 122. Although not shown in FIG. 2, it should be noted that the semiconductor device structure 100a may include other depletion regions located between doped regions and/or well regions with different conductivity types.

As shown in FIG. 3, an induced depletion region 128 may be generated when a cosmic ray L1 is incident on the semiconductor device structure 100a. The cosmic ray L1 may include high-energy particles or clusters of particles (e.g., protons, neutrons, or other particles). The induced depletion region 128 may extend from the depletion 126 and along a direction substantially same as or similar to the incident direction of the cosmic ray L1.

When the cosmic ray L1 passes through the semiconductor device structure 100a, multiple electron-hole pairs are generated, which thereby forms the induced depletion region 128. As a result, a drift current may be generated. Under conditions where the pick-up region 152 and/or pick-up region 154 is not formed, the drift current may be guided to the surface 102s2 of the substrate 102 through the well region 122 and the pick-up region 143a, passing across the isolation structure 250a. However, this path is relatively long. In this situation, the drift current induced by the cosmic ray L1 may cause electrical leakage.

In some embodiments of the present disclosure, the pick-up region 152 (or pick-up region 154) may be configured to provide a path for a drift current to flow out of the semiconductor device structure 100a through the surface 102s1 of the substrate 102 or to neutralize the carriers in the induced depletion region 128. As a result, electrical leakage can be reduced. In some embodiments, the pick-up region 152 (or pick-up region 154) is in contact with the induced depletion region 128. Therefore, a depth and/or a height of the pick-up region 152 may depend on a profile of the induced depletion region 128, which is influenced by the dopant concentrations of the S/D feature, well regions, and/or other doped regions.

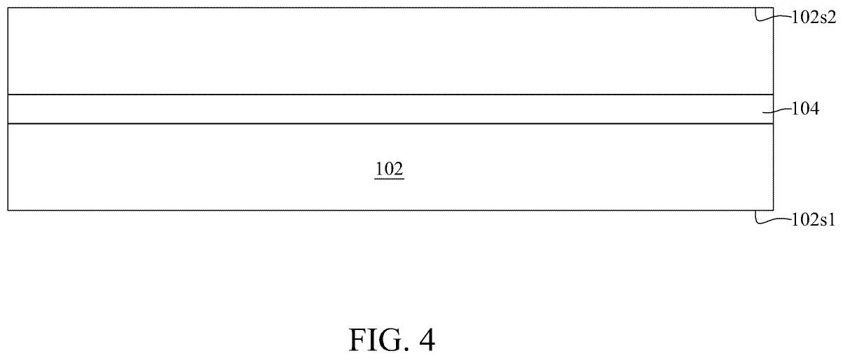

FIGS. 4 to 20 illustrate stages of an exemplary method of manufacturing a semiconductor device structure in accordance with some embodiments of the present disclosure.

Referring to FIG. 4, a substrate 102 may be provided. In some embodiments, the substrate 102 is a semiconductor-on-insulator (SOI) substrate. An isolation layer 104 may be disposed between a first portion (or lower portion) and a second portion (or upper portion) of the substrate 102. The isolation layer 104 may abut the second portion (or upper portion) of the substrate 102. The substrate 102 has a surface 102s1 and a surface 102s2 opposite to the surface 102s1.

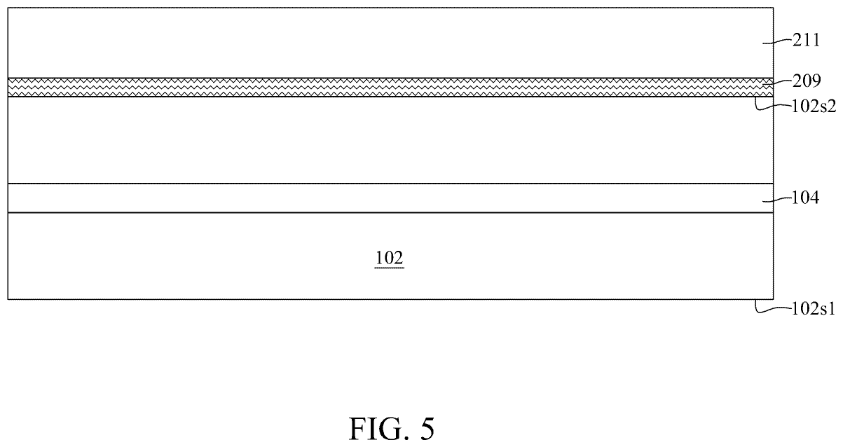

Referring to FIG. 5, a pad oxide layer 209 and a pad nitride layer 211 are sequentially formed over the substrate 201. In some embodiments, the pad oxide layer 209 is made of silicon oxide, such as SiO₂, and the pad nitride layer 211 is made of silicon nitride, such as Si₃N₄. The pad oxide layer 209 and the pad nitride layer 211 may be formed by thermal oxidation, CVD, ALD and/or other applicable methods.

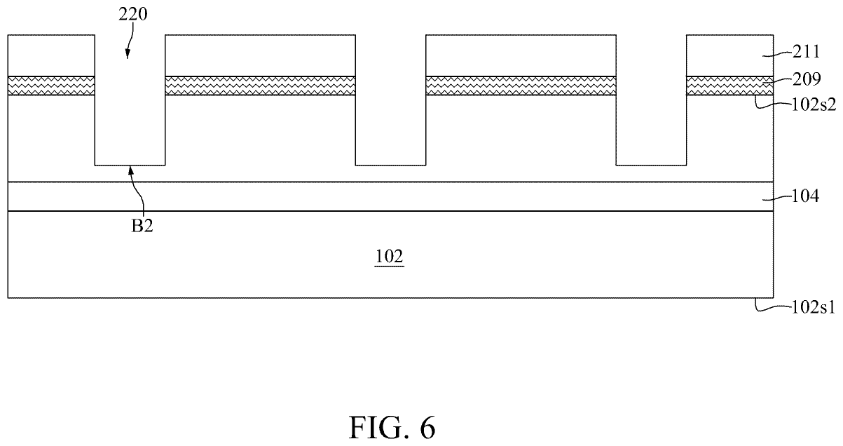

Referring to FIG. 6, a shallow trench 220 is formed penetrating through the pad nitride layer 211 and the pad oxide layer 209 and extending into the second portion (or upper portion) of the substrate 102. In some embodiments, a bottom surface B2 of the shallow trench 220 is located in the second portion (or upper portion) of the substrate 102 and higher than a bottom surface the second portion (or upper portion) of the substrate 102. In some embodiments, the formation of the shallow trench 220 includes forming a patterned mask over the pad nitride layer 211, and etching the underlying structure by using the patterned mask as a mask. The etching may be performed using a wet etching process, a dry etching process, or a combination thereof. After the formation of the shallow trench 220, the patterned mask is removed using, for example, an ashing process followed by a wet cleaning process.

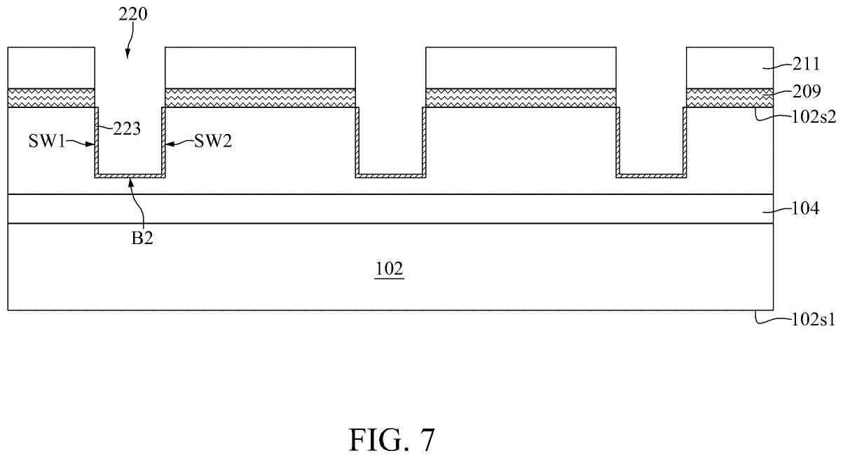

Referring to FIG. 7, a first liner layer 223 is formed over sidewalls SW1 and SW2 and the bottom surface B2 of the shallow trench 220. More specifically, the exposed sidewalls SW1 and SW2 and the exposed surface of the second portion (or upper portion) of the substrate 102 (i.e., the bottom surface B2 of the shallow trench 220) are covered by and in direct contact with the first liner layer 223, while sidewalls of the pad nitride layer 211, the pad oxide layer 209 in the shallow trench 220 are at least partially exposed. In some embodiments, the first liner layer 223 is made of silicon oxide, such as SiO₂, and is formed by an oxidation process.

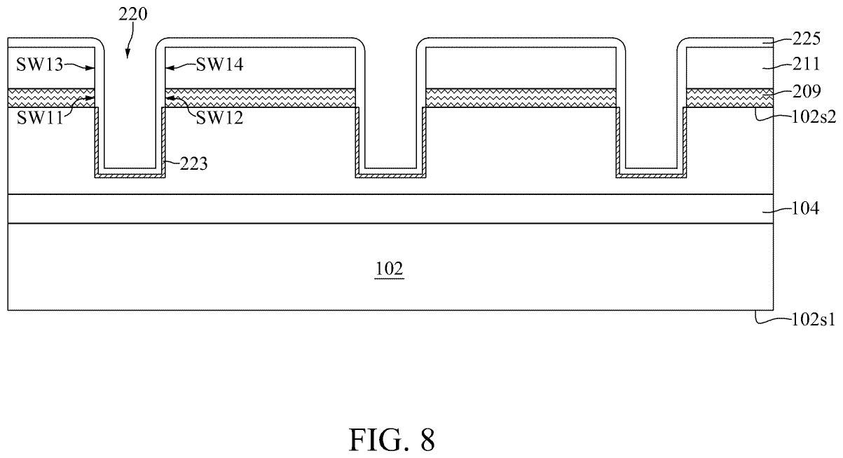

Referring to FIG. 8, a second liner layer 225 may be deposited over the first liner layer 223. The second liner layer 225 is conformally formed over top surface of the pad nitride layer 211 and lining the remaining portion of the shallow trench 220. In some embodiments, the first liner layer 223 is completely covered by the second liner layer 225, and the exposed sidewalls SW13 and SW14 of the pad nitride layer 211, the exposed sidewalls SW11 and SW12 of the pad oxide layer 209 are covered by and in direct contact with the second liner layer 225. In some embodiments, the second liner layer 225 is made of nitride, such as silicon nitride, and is formed by nitridation process, such as a rapid thermal nitridation (RTN) process.

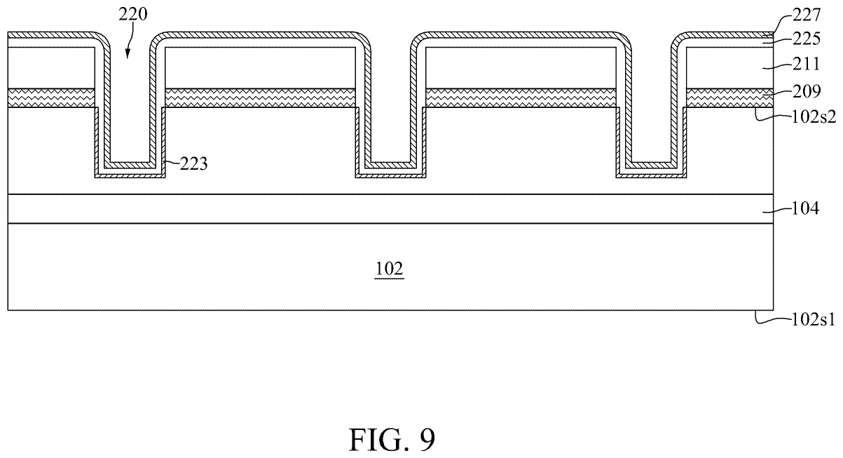

Referring to FIG. 9, a third liner layer 227 is formed over the second liner layer 225. In some embodiments, the third liner layer 227 is conformally formed over a top surface of the pad nitride layer 211 and lining the remaining portion of the shallow trench 220. In some embodiments, the third liner layer 127 is made of silicon oxynitride, and is formed by an in-situ steam generation (ISSG) process.

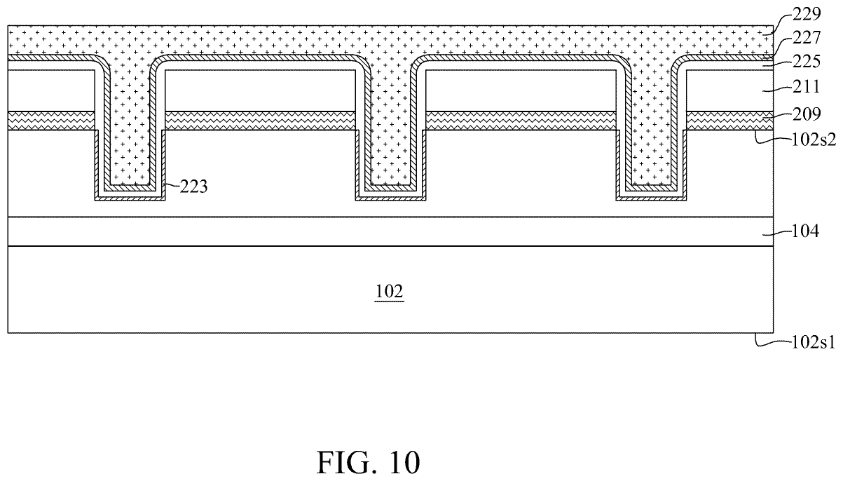

Referring to FIG. 10, a trench filling layer 229 is formed over the third liner layer 227 and filling the remaining portion of the shallow trench 220. In some embodiments, the trench filling layer 229 is made of a dielectric material, such as silicon oxide, silicon nitride, silicon oxynitride, silicon carbonitride, silicon oxide carbonitride, or a combination thereof. It should be noted that the material of the trench filling layer 229 is different from the materials of the second liner layer 225 and the third liner layer 227, ensuring that sufficient etching selectivity between the second liner layer 225 and the trench filling layer 229, and between the third liner layer 227 and the trench filling layer 229. Moreover, the trench filling layer 229 may be formed by a deposition process, such as a CVD process or an ALD process.

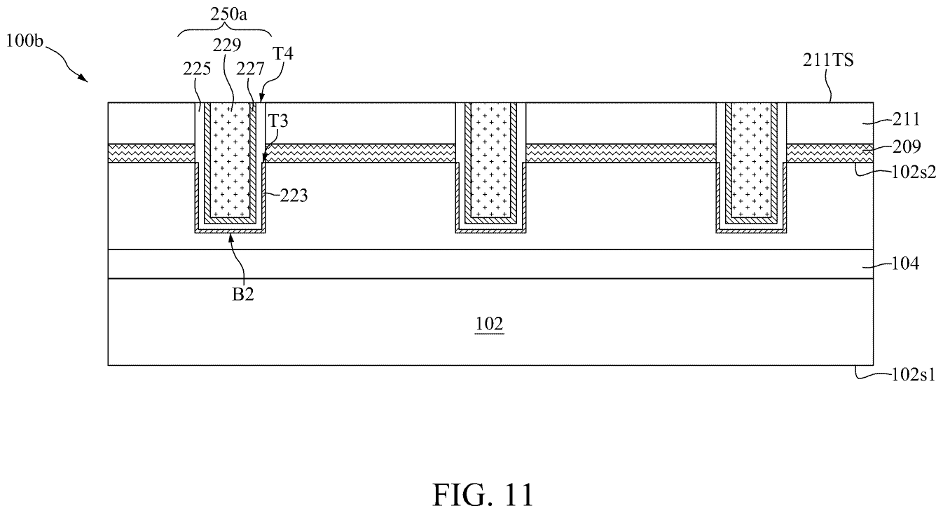

Referring to FIG. 11, a planarization process is performed on the trench filling layer 229, the third liner layer 227, and the second liner layer 225 to expose a top surface 211TS of the pad nitride layer 211, such that top surfaces of the trench filling layer 229, the third liner layer 227, and the second liner layer 225 are substantially coplanar with each other. In some embodiments, the planarization process is a CMP process. After the planarization process, an isolation structure 250a is formed, and a semiconductor device structure 100b is obtained.

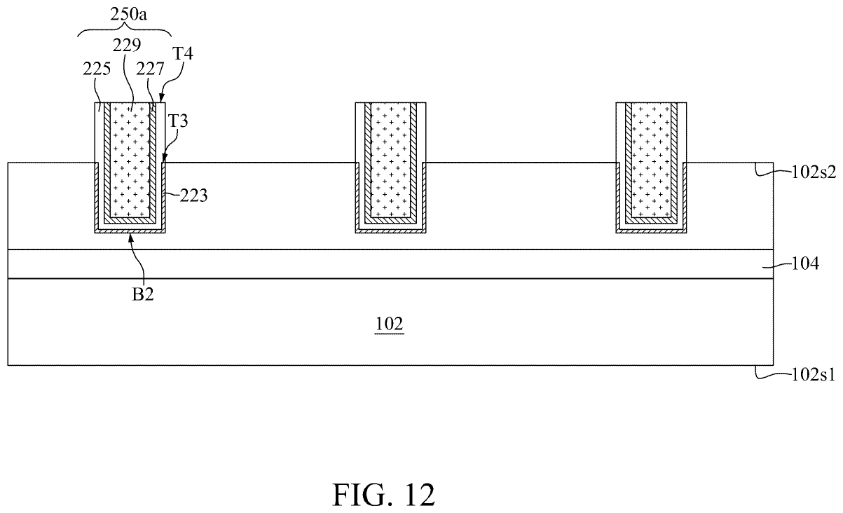

Referring to FIG. 12, the pad nitride layer 211 shown in FIG. 11 may be removed. In some embodiments, the removal of the pad nitride layer 211 may be performed by an isotropic etching process, such as a dry etching process, until the surface 102s2 of the second portion (or upper portion) of the substrate 102 is exposed.

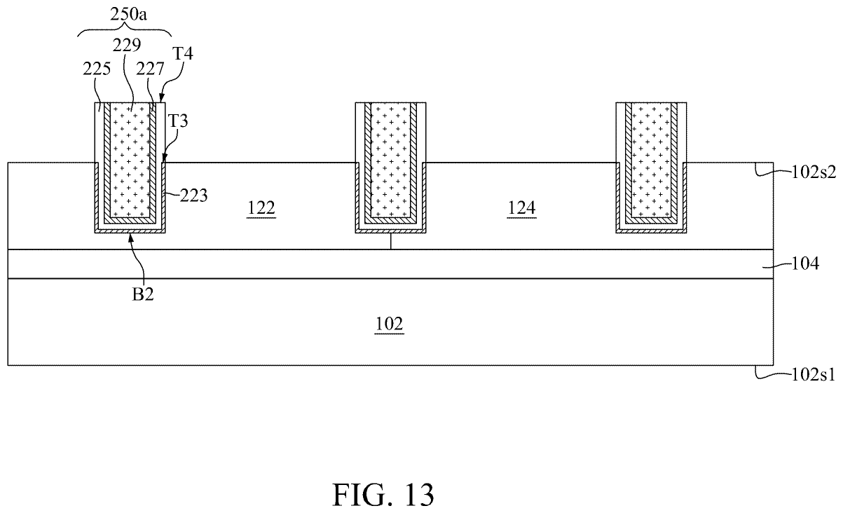

Referring to FIG. 13, a well region 122 and a well region 124 may be formed. The well region 122 may be formed within the second portion (or upper portion) of the substrate 102. The well region 124 may be formed within the second portion (or upper portion) of the substrate 102.

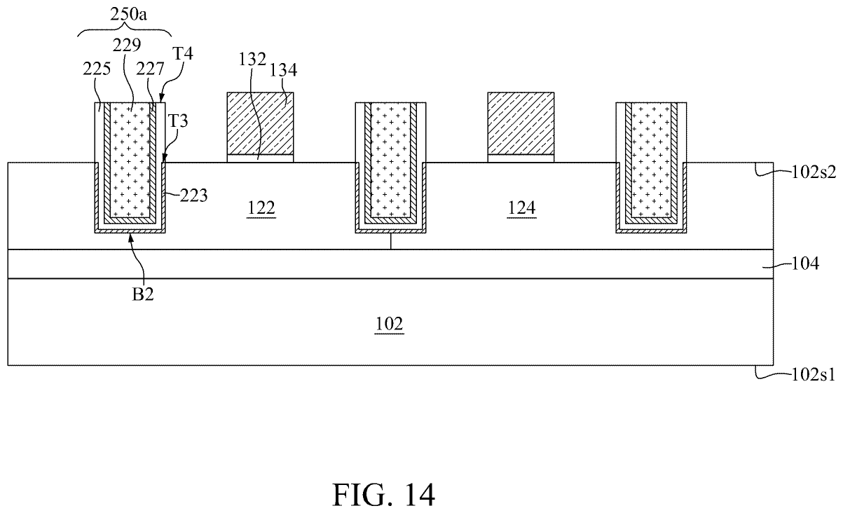

Referring to FIG. 14, a gate dielectric layer 132 and a gate electrode 134 may be formed on or over the surface 102s2 of the substrate 102. In some embodiments, a gate dielectric material and a gate electrode material may be formed by ALD, CVD, FCVD, or other suitable techniques. Further, an etching technique(s) may be performed to pattern the gate dielectric material and a gate electrode material, which thereby forms the gate dielectric layer 132 and the gate electrode 134.

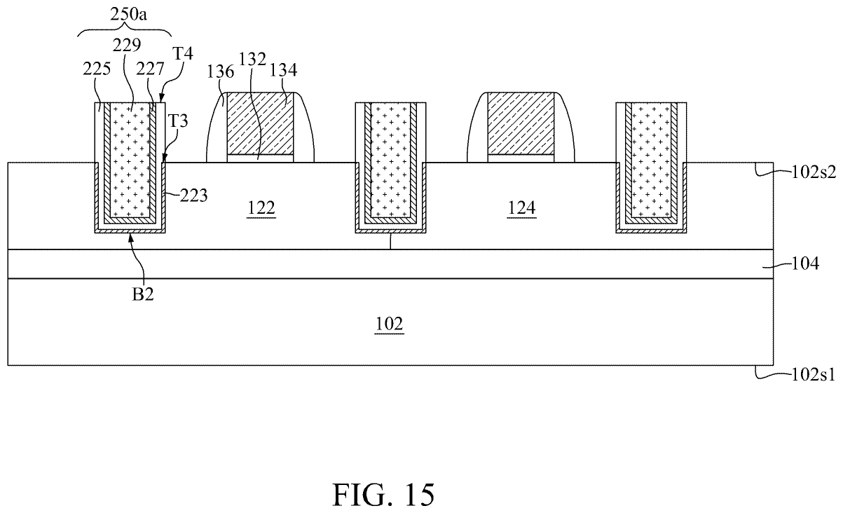

Referring to FIG. 15, a spacer 136 may be formed on two opposite sides of the gate dielectric layer 132 and the gate electrode 134. The spacer 136 may be formed by ALD, CVD, and/or FCVD as well as etching techniques.

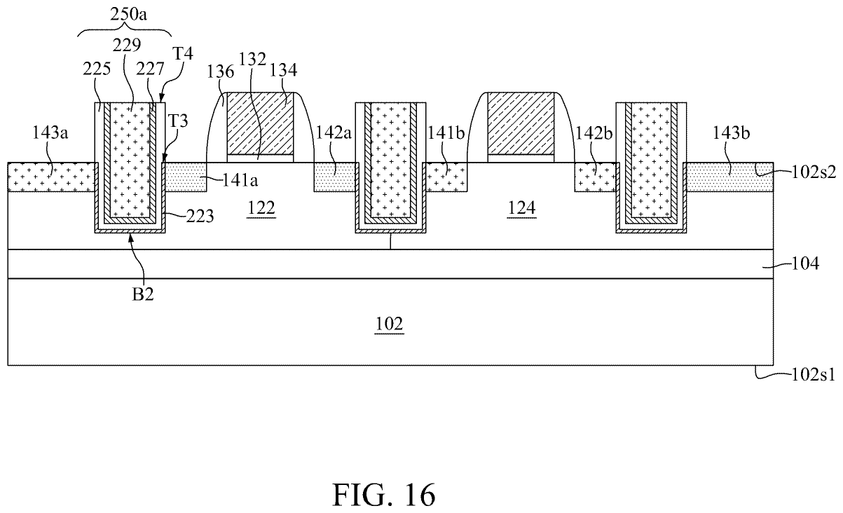

Referring to FIG. 16, doped regions 141a, 141b, 142a, and 142b may be formed adjacent to the surface 102s2 of the substrate 102. Pick-up regions 143a and 143b may be formed abutting the surface 102s2 of the substrate 102. The doped region 141a, the doped region 142a, and the pick-up region 143a may be formed within the well region 122. The doped region 141b, the doped region 142b, and the pick-up region 143b may be formed within the well region 124.

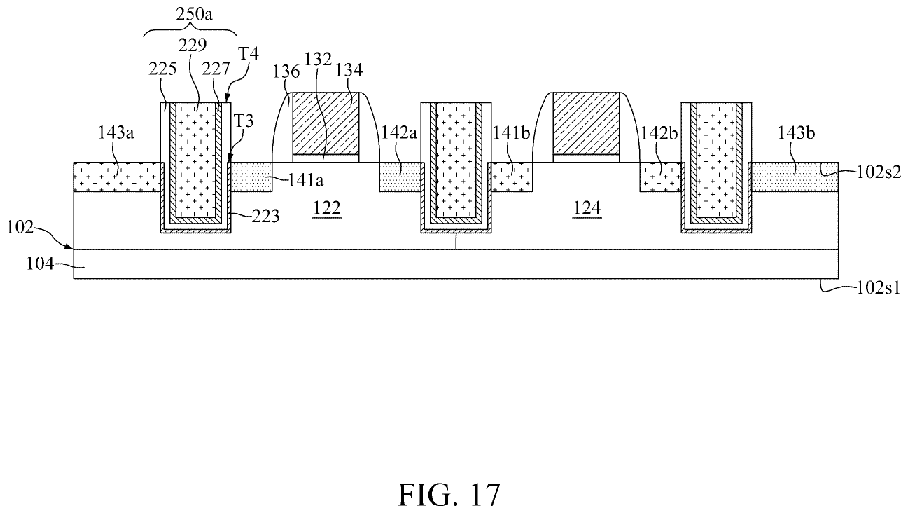

Referring to FIG. 17, a portion (e.g., the lower portion) of the substrate 102 may be removed. The isolation layer 104 may be exposed. A grinding technique or a polishing technique (e.g., a chemical mechanical polishing technique) may be performed to remove the lower portion of the substrate 102. It should be noted that, after the grinding or polishing, the substrate 102 (e.g., the upper portion) may have a surface 102s1 between the substrate 102 and the isolation layer 104.

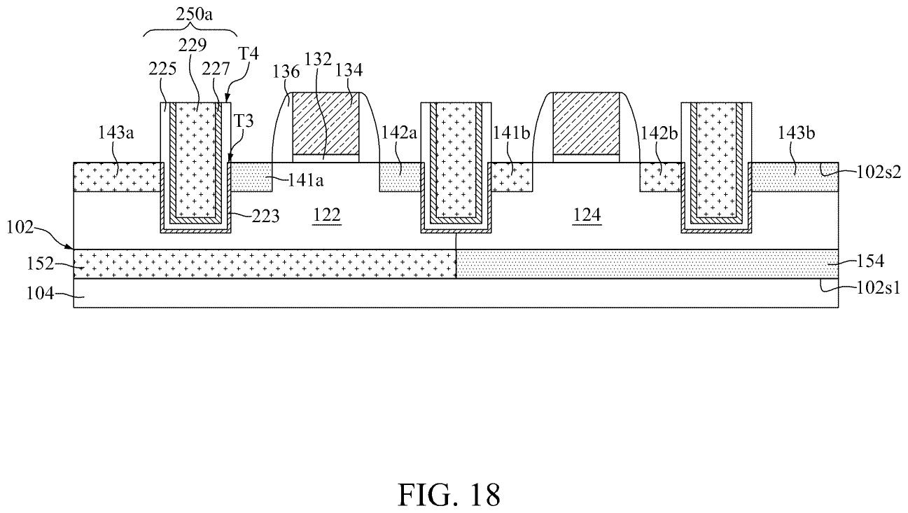

Referring to FIG. 18, a pick-up region 152 and a pick-up region 154 may be formed. The pick-up region 152 may abut the surface 102s1 of the substrate 102. The pick-up region 152 may be in contact with or abut the well region 122. The pick-up region 154 may abut the surface 102s1 of the substrate 102. The pick-up region 154 may be in contact with or abut the well region 124. In some embodiments, dopants may be implanted to the substrate 102 through the surface 102s1 of the substrate 102, which thereby forms the pick-up regions 152 and 154.

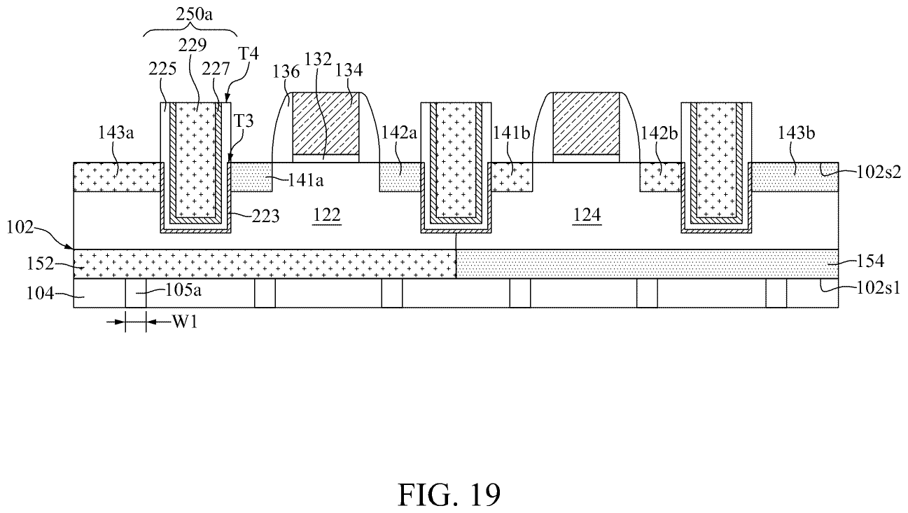

Referring to FIG. 19, a first portion 105a of a conductive via 105 may be formed in the isolation layer 104. The first portion 105a may be disposed on or under the surface 102s1 of the substrate 102. In some embodiments, the first portion 105a extends through and is surrounded by the isolation layer 104. The first portion 105a may be in contact with or electrically connected to the pick-up region 152 (or 154). In some embodiments, the first portion 105a includes conductive materials, such as gold, silver, copper, nickel, tungsten, aluminum, tin, alloys thereof or the like. In some embodiments, the first portion 105a may have a width W1 that is in a range of about 2 um to about 10 um.

In some embodiments, an etching technique may be performed to pattern the isolation layer 104, which thereby defines openings. Then, a conductive material(s) may be formed within the openings to form the first portion 105a. In some embodiments, the conductive material(s) may be formed by a physical vapor deposition (PVD), ALD, CVD, or a combination thereof.

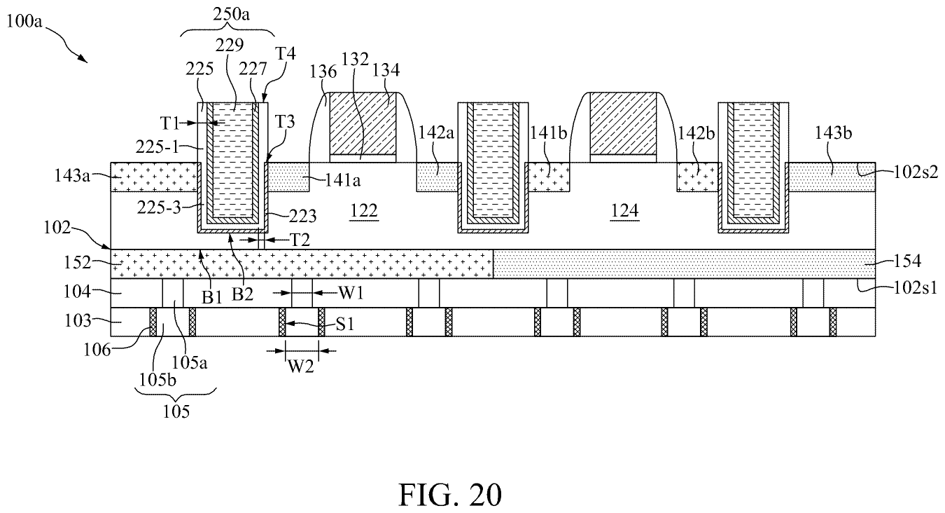

Referring to FIG. 20, a second portion 105b of the conductive via 105, a dielectric liner 106 and a passivation layer 103 may be formed on or under the isolation layer 104. As a result, a semiconductor device structure 100a (e.g., the semiconductor device structure as shown in FIG. 1) may be produced.

The passivation layer 103 may be disposed on or under the isolation layer 104. In some embodiments, the passivation layer 103 includes dielectric materials, such as spin-on glass (SOG), silicon oxide, silicon oxynitride, silicon nitride, or the like. In other embodiments, the passivation layer 103 may include polymers, BCB, PBO, PI, or other suitable materials. In some embodiments, the passivation layer 103 may be formed by a physical vapor deposition (PVD), ALD, CVD, spin coating, or a combination thereof.

The second portion 105b of the conductive via 105 may be disposed on or under the first portion 105a. The second portion 105b extends through and is surrounded by the passivation layer 103 and is coupled with the first portion 105a. In some embodiments, the second portion 105b of the conductive via 105 may have a width W2 that is substantially greater than the width W1 of the first portion 105a. The width W2 of the second portion 105b may be in a range of about 4 μm to about 10 μm. In some embodiments, the width W2 of the second portion 105b is about 7 μm. Materials and processes used for the formation of the second portion 105b of the conductive via 105 are similar to, or same as those used for the formation of the first portion 105a of the conductive via 105, and details thereof are not repeated herein.

The dielectric liner 106 may be positioned between the conductive via 105 and the passivation layer 103. In some embodiments, a top surface of the dielectric liner 106 is substantially coplanar with a top surface of the passivation layer 103 and a top surface of the second portion 105b of the conductive via 105. In some embodiments, the dielectric liner 106 is disposed between the second portion 105b and the passivation layer 103. The dielectric liner 106 extends vertically along a sidewall S1 of the second portion 105b and through the passivation layer 103. In some embodiments, the dielectric liner 106 is disposed on or below and in contact with the isolation layer 104. In some embodiments, the dielectric liner 106 may include a dielectric material, such as an oxide or the like. In some embodiments, the dielectric liner 106 is formed by deposition, atomic layer deposition (ALD), CVD or another suitable operation.

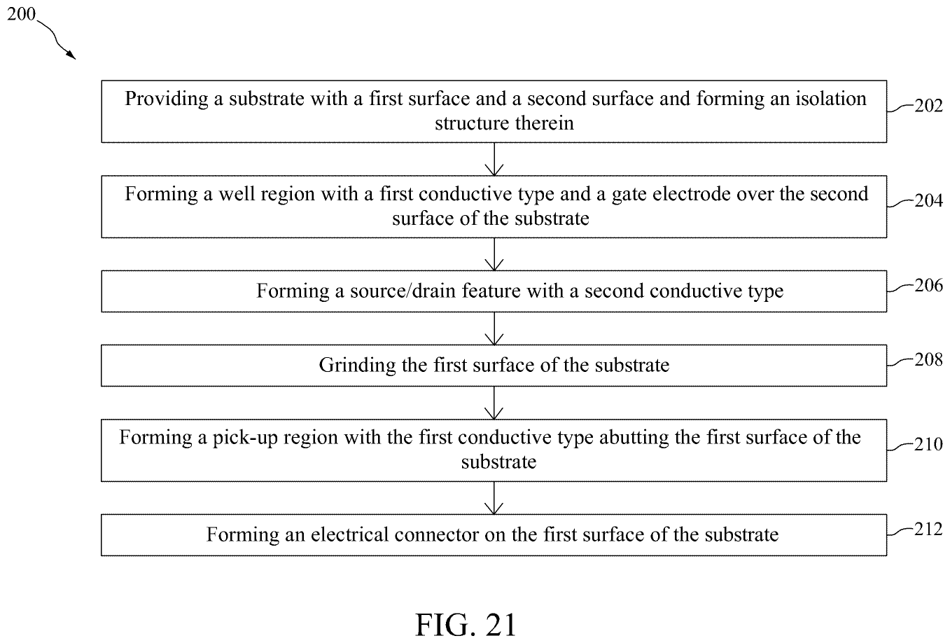

FIG. 21 is a flowchart illustrating a method 200 of manufacturing the semiconductor device structure 100a in accordance with some embodiments of the present disclosure.

The method 200 may begin with operation 202, in which a substrate 102 is provided. The substrate 102 may have a first surface 102s1 and a second surface 102s2. The substrate 102 may include a semiconductor-on-insulator substrate with an isolation layer 104 and an isolation structure 205a disposed therein. FIGS. 4 to 12 depicts stages with reference to operation 202.

The method 200 may continue with operation 204, in which a well region 122 or 144 is formed within the substrate 102 and a gate electrode 134 is formed over the second surface 102s2 of the substrate 102. The well region 122 or 124 has a first conductivity type. Further, a spacer 136 may be formed on two opposite sides of the gate electrode 134. FIGS. 13 to 15 depict stages with reference to operation 204.

The method 200 may continue with operation 206, in which an S/D feature 141a/142a or 141b/142b is formed. The S/D feature 141a/142a or 141b/142b has a second conductivity type different from the first conductivity type. The S/D feature 141a/142a or 141b/142b abuts the second surface 102s2 of the substrate 102. Further, a first pick-up region 143a or 143b may be formed. The first pick-up region 143a or 143b abuts the second surface 102s2 of the substrate 102 and has the first conductivity type. FIG. 16 depicts a stage with reference to operation 206.

The method 200 may continue with operation 208, in which the first surface 102s1 of the substrate 102 is grinded or polished. The isolation layer 104 may be exposed. FIG. 17 depicts a stage with reference to operation 208.

The method 200 may continue with operation 210, in which a second pick-up region 152 or 154 may be formed. The second pick-up region 152 or 154 abuts the first surface 102s1 of the substrate 102 and has the first conductivity type. The second pick-up region 152 or 154 vertically overlap the S/D feature 141a/142a or 141b/142b. The second pick-up region 152 or 154 is configured to guide or neutralize a drift current from an induced depletion region 128 of the S/D feature 141a/142a or 141b/142b caused by a cosmic ray LI toward the first surface 102s1 of the substrate 102. FIG. 18 depicts a stage with reference to operation 210.

The method 200 may continue with operation 212, in which a passivation layer 103 is formed on the isolation layer 104, and electrical connectors (e.g., conductive vias 105) are formed within the isolation layer 104 and the passivation layer 103. The conductive via 105 consists of a first portion 105a disposed on or under the surface 102s1 of the substrate 102 and a second portion 105b disposed on or under the first portion 105a. FIGS. 19 and 20 depict stages with reference to operation 212.

The method 200 is merely an example, and is not intended to limit the present disclosure beyond what is explicitly recited in the claims. Additional operations can be provided before, during, or after each operations of the method 200, and some operations described can be replaced, eliminated, or reordered for additional embodiments of the method. In some embodiments, the method 200 can include further operations not depicted in FIG. 21. In some embodiments, the method 200 can include one or more operations depicted in FIG. 21.

One aspect of the present disclosure provides a semiconductor device structure. The semiconductor device structure includes a substrate having a first surface and a second surface opposite to the first surface; an isolation structure disposed in the substrate and protruding from the second surface of the substrate; a first well region abutting the second surface of the substrate and having a first conductivity type; a source/drain (S/D) feature abutting the second surface of the substrate and having a second conductivity type different from the first conductivity type; and a first pick-up region abutting the first surface of the substrate and having the first conductivity type. The isolation structure comprises a first liner layer disposed in the substrate, a second liner layer disposed over the first liner layer and protruding from the second surface of the substrate, a third liner layer disposed over the second liner layer, and a trench filling layer disposed over the third liner layer. The second liner layer includes a lower portion disposed in the substrate and an upper portion disposed on the lower portion and protruding from the second surface of the substrate. A thickness of the upper portion is greater than a thickness of the lower portion.

One aspect of the present disclosure provides a semiconductor device structure. The semiconductor device structure includes a substrate having a first surface and a second surface opposite to the first surface; an isolation layer disposed in the substrate and parallel to the first surface and the second surface; a pad oxide layer disposed over the second surface of the substrate; a pad nitride layer disposed over the pad oxide layer; and an isolation structure extending from a top surface of the pad nitride layer, penetrating the pad nitride layer and the pad oxide layer, and into the substrate. The isolation structure comprises a first liner layer disposed in the substrate, a second liner layer disposed over the first liner layer, a third liner layer disposed over the second liner layer, and a trench filling layer disposed over the third liner layer. The second liner layer includes an upper portion located between the pad oxide layer and the third liner layer and between the pad nitride layer and the third liner layer, and a lower portion located between the first liner layer and the third liner layer. A thickness of the upper portion of the second liner layer is greater than a thickness of the lower portion of the second liner layer.

Another aspect of the present disclosure provides a method of manufacturing a semiconductor device structure. The method includes providing a substrate having a first surface and a second surface opposite to the first surface; forming a pad oxide layer over the second surface of the substrate; forming a pad nitride layer over the pad oxide layer; forming an isolation structure extending from a top surface of the pad nitride layer, penetrating the pad nitride layer and the pad oxide layer, and into the substrate; forming a first well region abutting the second surface of the substrate; forming a source/drain (S/D) feature abutting the second surface of the substrate; and forming a pick-up region abutting the first surface of the substrate. The first well region has a first conducive type, the S/D feature has a second conductivity type different from the first conductivity type, and the pick-up region has the first conductivity type.

Another aspect of the present disclosure provides a method of manufacturing a semiconductor device structure. The method includes providing a substrate with an isolation layer disposed therein, wherein the substrate has a first surface and a second surface opposite to the first surface; forming a pad oxide layer over the second surface of the substrate; forming a pad nitride layer over the pad oxide layer; and forming an isolation structure extending from a top surface of the pad nitride layer, penetrating the pad nitride layer and the pad oxide layer, and into the substrate.

The embodiments of the present disclosure provide a semiconductor device structure. The semiconductor device structure includes a pick-up region and a source/drain feature on opposite two surfaces of a substrate. The pick-up region is configured to provide a low-resistance path for a drift current to flow out of the semiconductor device structure through a backside surface. The pick-up region can provide a relatively short path for transmitting the drift current and reduce the leakage caused by a cosmic ray incident to the semiconductor device structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device structure, comprising:
a substrate having a first surface and a second surface opposite to the first surface;
an isolation structure disposed in the substrate and protruding from the second surface of the substrate, wherein the isolation structure comprises:
a first liner layer disposed in the substrate;
a second liner layer disposed over the first liner layer and protruding from the second surface of the substrate;
a third liner layer disposed over the second liner layer; and
a trench filling layer disposed over the third liner layer,
wherein the second liner layer includes a lower portion disposed in the substrate and an upper portion disposed on the lower portion and protruding from the second surface of the substrate, wherein a thickness of the upper portion is greater than a thickness of the lower portion;
a first well region abutting the second surface of the substrate and having a first conductivity type;
a source/drain (S/D) feature abutting the second surface of the substrate and having a second conductivity type different from the first conductivity type; and
a first pick-up region abutting the first surface of the substrate and having the first conductivity type.

2. The semiconductor device structure of claim 1, wherein the first pick-up region is exposed by the first surface of the substrate.

3. The semiconductor device structure of claim 1, wherein a material of the trench filling layer is different from materials of the second liner layer and the third liner layer.

4. The semiconductor device structure of claim 1, wherein the first liner layer is completely covered by the second liner layer.

5. The semiconductor device structure of claim 1, wherein a top surface of the second liner layer is higher than a top surface of the first liner layer.

6. The semiconductor device structure of claim 5, wherein top surfaces of the second liner layer, the third liner layer and the trench filling layer are substantially coplanar.

7. The semiconductor device structure of claim 1, further comprising:
a conductive via, comprising:
a first portion disposed on the first pick-up region and electrically connected to the first pick-up region; and
a second portion disposed on the first portion, wherein a width of the first portion is substantially less than a width of the second portion.

8. The semiconductor device structure of claim 7, further comprising an isolation layer disposed on the surface of the substrate and a passivation layer disposed on the isolation layer.

9. The semiconductor device structure of claim 8, wherein the first portion of conductive via is disposed in the isolation layer and the second portion is disposed in the passivation layer.

10. The semiconductor device structure of claim 9, further comprising a dielectric liner disposed in the passivation layer and between the second portion of the conductive via and the passivation layer.

11. The semiconductor device structure of claim 7, wherein the conductive via is electrically connected to ground.

12. The semiconductor device structure of claim 1, wherein the first pick-up region is configured to be in contact with an induced depletion region between the first well region and the S/D feature when a cosmic ray is incident on the semiconductor device structure.

13. The semiconductor device structure of claim 1, further comprising:
a second pick-up region abutting the second surface of the substrate and having the second conductivity type, wherein the second pick-up region is spaced apart from the S/D feature by the isolation structure.

14. The semiconductor device structure of claim 13, wherein a dopant concentration of the second pick-up region is substantially equal to a dopant concentration of the first pick-up region.
